(19) United States
(12) Patent Application Publication
(10) Pub. No.: US 2016/0111254 A1
(43) Pub. Date: Apr. 21, 2016

(54) Workpiece Processing Method And Apparatus

(71) Applicant: Varian Semiconductor Equipment Associates, Inc., Gloucester, MA (US)

(72) Inventors: Morgan D. Evans, Manchester, MA (US); Kevin Anglin, Somerville, MA (US); Daniel Distaso, Merrimac, MA (US); John Hautala, Beverly, MA (US); Steven Robert Sherman, Newton, MA (US); Joseph C. Olson, Beverly, MA (US)

(21) Appl. No.: 14/878,519

(22) Filed: Oct. 8, 2015

Related U.S. Application Data
(60) Provisional application No. 62/064,740, filed on Oct. 16, 2014.

(51) Int. Cl. H01J 37/32; C23C 14/22; C23C 14/54; C23C 14/48

(52) U.S. Cl. CPC H01J 37/32009; H01J 37/32715; H01J 37/32752; H01J 37/32412; C23C 14/48; C23C 14/221; C23C 14/54; H01J 2237/334; H01J 2237/3365; H01J 2237/336; H01J 2237/332

(57) ABSTRACT

A system and method for processing a workpiece is disclosed. A plasma chamber is used to create a ribbon ion beam, extracted through an extraction aperture. A workpiece is translated proximate the extraction aperture so as to expose different portions of the workpiece to the ribbon ion beam. As the workpiece is being exposed to the ribbon ion beam, at least one parameter associated with the plasma chamber is varied. The variable parameters include extraction voltage duty cycle, workpiece scan velocity and the shape of the ion beam. In some embodiments, after the entire workpiece has been exposed to the ribbon ion beam, the workpiece is rotated and exposed to the ribbon ion beam again, while the parameters are varied. This sequence may be repeated a plurality of times.

This application claims priority of U.S. Provisional Patent Application Ser. No. 62/064,740, filed Oct. 16, 2014, the disclosure of which is incorporated herein by reference in its entirety.

### FIELD

Embodiments of this disclosure are directed to systems and methods for processing workpieces.

### BACKGROUND

Plasma chambers are often used to generate a plasma. Ions from this plasma are then extracted from the plasma chamber through an aperture to form an ion beam. This plasma may be generated in various ways. In one embodiment, an antenna is disposed outside the plasma chamber, proximate to a dielectric window. The antenna is then excited using an RF power supply. The electromagnetic energy generated by the antenna then passes through the dielectric window to excite feed gas disposed within the plasma chamber.

The plasma that is generated is then extracted through an extraction aperture. In some embodiments, the extraction aperture may be rectangular or oval, where the length is much larger than the width of the opening. The extracted ion beam may be a ribbon ion beam. However, in these embodiments, the ribbon ion beam that is extracted from the plasma chamber may not be of the desired uniformity across the length of extraction aperture. For example, the ion density may be greater near the center of the ribbon ion beam and may be reduced in regions away from the center.

Furthermore, in some embodiments, it is desirable to process a workpiece in a non-uniform manner, such that certain regions of the workpiece are processed more than other regions. Therefore, it would be beneficial if there were an improved system and method for processing workpieces that was able to achieve the desired processing. More particularly, it would be advantageous to more finely control the uniformity of one or more parameters of a workpiece being processed using a plasma chamber.

### SUMMARY

A system and method for processing a workpiece is disclosed. A plasma chamber is used to create a ribbon ion beam, extracted through an extraction aperture. A workpiece is translated proximate the extraction aperture so as to expose different portions of the workpiece to the ribbon ion beam. As the workpiece is being exposed to the ribbon ion beam, at least one parameter associated with the plasma chamber is varied. The variable parameters include extraction voltage duty cycle, workpiece scan velocity and the shape of the ion beam. In some embodiments, after at least some portions of the workpiece have been exposed to the ribbon ion beam, the workpiece is rotated and exposed to the ribbon ion beam again, while the parameters are varied. This sequence may be repeated a plurality of times.

According to a first embodiment, a method of processing a workpiece using a plasma chamber is disclosed. The method comprises extracting a ribbon ion beam through an extraction aperture of the plasma chamber; translating the workpiece relative to the plasma chamber so that different portions of the workpiece are exposed to the ribbon ion beam; and varying at least one parameter of the plasma chamber while the workpiece is being translated. In some embodiments, the method further comprises rotating the workpiece after at least some portions of the workpiece have been exposed to the ribbon ion beam; and repeating the translating, varying and rotating a plurality of times to achieve a desired pattern.

According to a second embodiment, a method of etching a workpiece having a non-uniform thickness is disclosed. The method comprises determining an etch pattern that removes the non-uniform thickness; and applying the etch pattern to the workpiece using a ribbon ion beam extracted from a plasma chamber.

According to a third embodiment, a system for processing a workpiece is disclosed. The system comprises a plasma chamber having an extraction aperture from which a ribbon ion beam is extracted; a movable surface on which the workpiece is disposed so as to pass proximate the extraction aperture; and a controller; where the controller is configured to vary one or more parameters of the plasma chamber while the workpiece is passing the extraction aperture.

### BRIEF DESCRIPTION OF THE FIGURES

For a better understanding of the present disclosure, reference is made to the accompanying drawings, which are incorporated herein by reference and in which:

FIG. 1 shows a side view of a first embodiment of a plasma chamber;

FIGS. 2A-2C show various workpieces before processing;

FIG. 3A shows a workpiece before processing;

FIG. 3B shows the workpiece of FIG. 3A after processing;

FIG. 4 shows a representative illustration of the regions of a workpiece;

FIG. 5A shows a side view of a second embodiment of a plasma chamber;

FIG. 5B shows a bottom view of the plasma chamber of FIG. 5A;

FIG. 6 shows a bottom view of a plasma chamber according to another embodiment;

FIG. 7 shows a workpiece processing system with a controller; and

FIG. 8 illustrates a representative flowchart executed by the controller.

### DETAILED DESCRIPTION

A system and method of processing workpieces is disclosed. In some embodiments, the workpiece has already been pre-processed and the pre-processed workpiece is not uniform with respect to at least one parameter. For example, a workpiece may have a non-uniform amount of material deposited in a previous process. In other embodiments, a workpiece may have a non-uniform amount of material etched in a previous process. Alternatively, in other embodiments, the workpiece may later be subjected to a non-uniform process. In these scenarios, it would be beneficial to correct for previous process non-uniformities, or adjust for future process non-uniformities. In some embodiments, the uniformity of the workpiece processing may be controlled by workpiece scan velocity or by variable bias duty cycle. In other embodiments, the uniformity of the workpiece processing can be controlled by manipulating the shape or density of the extracted ion beam.

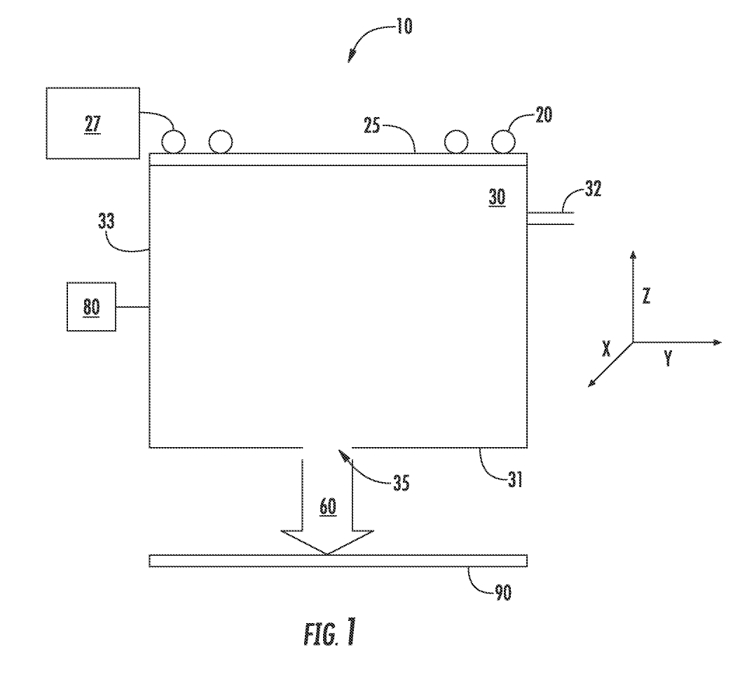

FIG. 1 shows a first embodiment of the workpiece processing system 10 for controlling the uniformity of one or more parameters of a workpiece 90 during processing. These parameters may include one or more of the following: amount of material deposited on the workpiece 90, amount of material etched from the workpiece 90, dose of ions implanted into the workpiece 90, and degree of amorphization performed on the workpiece 90.

An antenna 20 is disposed external to a plasma chamber 30, proximate a dielectric window 25. The antenna 20 is electrically connected to a RF power supply 27, which supplies an alternating voltage to the antenna 20. The voltage may be at a frequency of, for example, 2 MHz or more. While the dielectric window 25 and antenna 20 are shown on the top side of the plasma chamber 30, other embodiments are also possible. For example, the antenna 20 may surround the chamber sidewalls 33. The chamber walls of the plasma chamber 30 may be made of a conductive material, such as graphite. These chamber walls may be biased at an extraction voltage, such as by extraction power supply 80. The extraction voltage may be, for example, 1 kV, although other voltages are within the scope of the disclosure. In addition, the extraction voltage may be a square wave, having a frequency of between about 1 kHz and 50 kHz, although other frequencies are within the scope of the disclosure. In this embodiment, the extraction voltage may have an amplitude of Vₑₓₜ during a portion of its period and may be at ground potential during a second portion of its period.

The plasma chamber 30 includes a chamber wall 31 having an extraction aperture 35. This chamber wall 31 may be disposed on the side of the plasma chamber 30 opposite the dielectric window 25, although other configurations are also possible.

A workpiece 90 is disposed proximate and outside the chamber wall 31 having an extraction aperture 35 of the plasma chamber 30. In some embodiments, the workpiece 90 may be within about 1 cm of the chamber wall 31, although other distances are also possible. In operation, the antenna 20 is powered using a RF signal so as to inductively couple energy into the plasma chamber 30. This inductively coupled energy excites the feed gas introduced via gas inlet 32, thus generating a plasma. When the extraction voltage is at Vₑₓₜ, the chamber walls of the plasma chamber 30 are positively biased at Vₑₓₜ, and the plasma within the plasma chamber 30 is likewise positively biased. The workpiece 90, which may be grounded, is disposed proximate the chamber wall 31 having the extraction aperture 35. The difference in potential between the plasma and the workpiece 90 causes positively charged ions in the plasma to be accelerated through the extraction aperture 35 in the form of a ribbon ion beam 60 and toward the workpiece 90.

At those times when the extraction voltage is at ground potential, the chamber walls of the plasma chamber 30 are grounded. In this configuration, there is no potential difference between the plasma and the workpiece 90, and ions are not accelerated toward the workpiece 90. In other words, positive ions from the plasma are attracted to the workpiece 90 when the extraction voltage is positive regarding the workpiece 90.

The ribbon ion beam 60 may be at least as wide as the workpiece 90 in one direction, such as the x-direction, and may be much narrower than the workpiece 90 in the orthogonal direction (or y-direction). Further, the workpiece 90 may be translated relative to the extraction aperture 35 such that different portions of the workpiece 90 are exposed to the ribbon ion beam 60. The process wherein the workpiece 90 is translated so that the workpiece 90 is exposed to the ribbon ion beam 60 is referred to as “a pass”. A pass may be performed by translating the workpiece 90 while maintaining the position of the plasma chamber 30. The speed at which the workpiece 90 is translated relative to the extraction aperture 35 may be referred to as workpiece scan velocity. In another embodiment, the plasma chamber 30 may be translated while the workpiece 90 remains stationary. In other embodiments, both the plasma chamber 30 and the workpiece 90 may be translated. In some embodiments, the workpiece 90 moves at a constant workpiece scan velocity relative to the extraction aperture 35 in the y-direction, so that the entirety of the workpiece 90 is exposed to the ribbon ion beam 60 for the same amount of time.

Additionally, in some embodiments, the workpiece 90 may be exposed to the ribbon ion beam 60 a plurality of times. In other words, a plurality of passes may be performed on the workpiece 90. In some further embodiments, the workpiece 90 may be rotated about an axis parallel to the z-axis after each pass. For example, the workpiece may be exposed to the ribbon ion beam 60 a plurality of times, such as 4, 8 or 16 times. If the workpiece 90 is exposed to the ribbon ion beam 60 N times (i.e. undergoes N passes), the workpiece 90 may be rotated (360/N)° after each pass. In some embodiments, only some portions of the workpiece 90 are exposed to the ribbon ion beam 60 during each pass. This technique may reduce the effect of any non-uniformity of the ribbon ion beam 60. This technique also allows greater control over the desired uniformity of the parameter of interest.

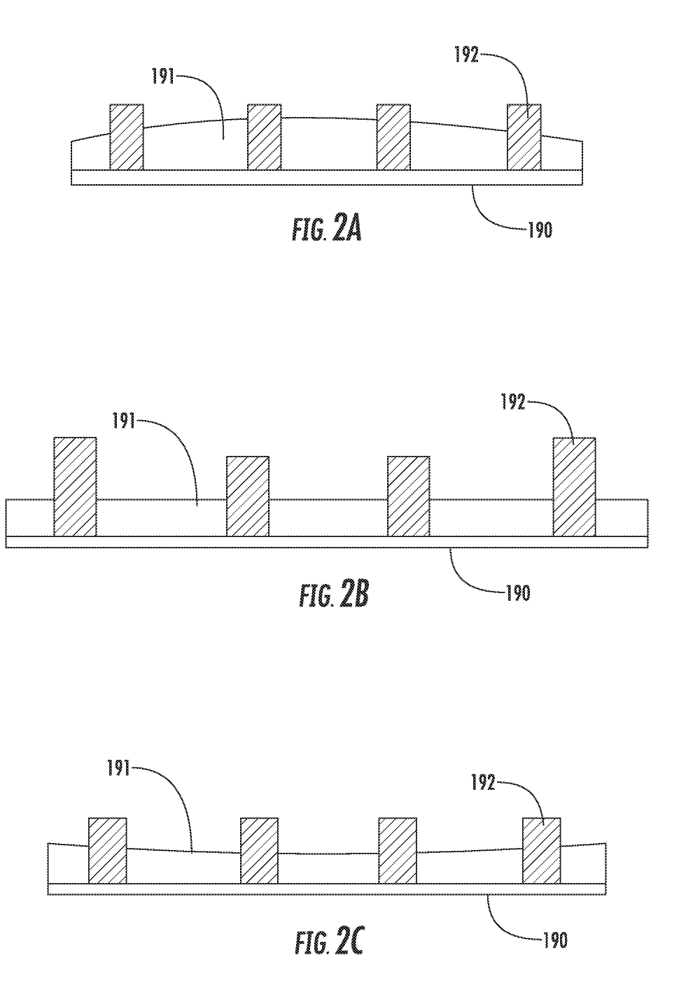

In some embodiments, the workpiece to be processed may not be uniform with respect to at least one parameter. For example, FIGS. 2A-C each show a workpiece 190 that was subjected to a prior deposition process. In each case, this workpiece 190 has a fill material 191 and a plurality of posts 192. In FIG. 2A, the posts 192 are of equal height; however, the fill material 191 is not evenly deposited. In FIG. 2B, the fill material 191 is evenly distributed; however, the posts 192 are not of equal height. In FIG. 2C, the fill material 191 is not evenly distributed. In FIGS. 2A-2B, this workpiece 190 may now be subjected to an etching process. In FIG. 2C, the workpiece 190 may now be subjected to a deposition process. In each case, it is desirous for the resulting workpiece to have a uniformly deposited fill material 191 and posts 192 of equal height, despite the non-uniformity of the pre-processed workpiece 190.

In one embodiment, the duty cycle of the extraction voltage may be varied to create the desired uniformity. For example, as explained above, ions are accelerated toward the workpiece 90 when the chamber walls of the plasma chamber 30 are more positively biased than the workpiece 90. Therefore, when the duty cycle of the extraction voltage is increased, ions are being accelerated toward the workpiece 90 a greater percentage of the time. Conversely, if the duty cycle is decreased, ions are accelerated toward the workpiece 90 less often. Thus, the amount of processing (i.e. implanting, etching, depositing, amorphizing) performed on the workpiece 90 may be adjusted by varying the duty cycle of the extraction voltage output from extraction power supply 80.

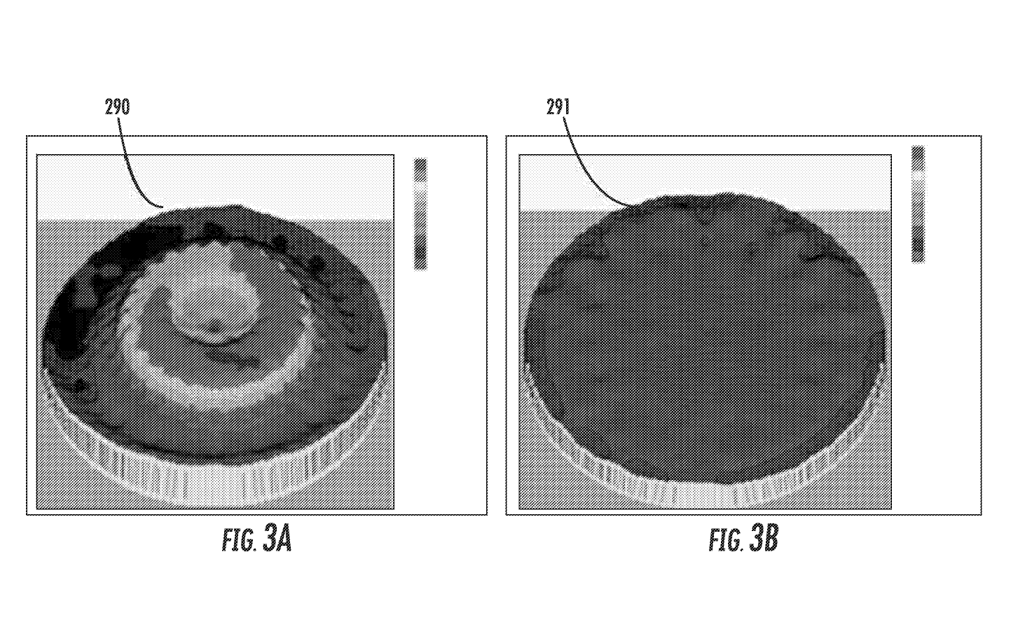

Therefore, in one embodiment, the processing of the workpiece 90 may be altered by varying the duty cycle of the extraction voltage. The extraction power supply 80 may be programmable, such that the duty cycle of its output voltage may be changed. In some embodiments, the amplitude of the voltage may also be modified. For example, FIG. 3A shows a workpiece 290 that has surface non-uniformity. This workpiece 290 may have surface non-uniformity in excess of 100 angstroms. In other words, the distance in thickness between the thinnest portion of the workpiece 290 and the thickest portion of the workpiece 290 may be in excess of 100 angstroms. To correct this, more material may be etched from the center of the workpiece 290 than from the edges of the workpiece 290. As the workpiece 290 is translated relative to the extraction aperture 35, the duty cycle of the extraction voltage may be modulated.

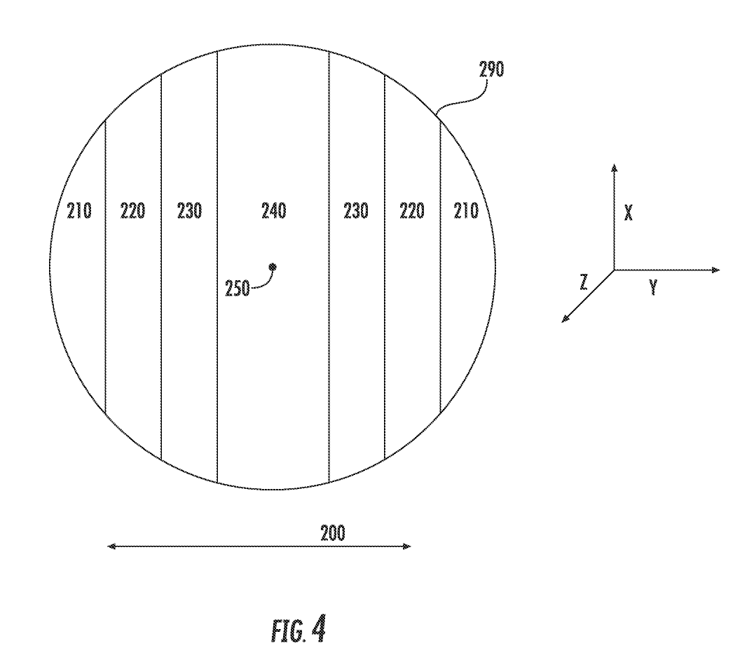

For example, FIG. 4 shows the workpiece 290, which is moved laterally (i.e. in the y-direction) relative to the extraction aperture 35, as indicated by arrows 200. In this illustration, the duty cycle of the extraction voltage may have four different values. When regions 210 of the workpiece 290 are exposed to the ribbon ion beam 60, the lowest duty cycle is applied. When regions 220 of the workpiece 290 are exposed, a first intermediate duty cycle is applied. Similarly, when regions 230 of the workpiece 290 are exposed, a second intermediate duty cycle, greater than the first, is applied. Finally, when region 240, which represented the region near the center of the workpiece 290, is exposed to the ribbon ion beam 60, the greatest duty cycle is applied. Thus, four different regions 210-240 are created, when the processing of the workpiece 290 is different in each region. Of course, more or fewer than four regions can be created on the workpiece 290.

In some embodiments, the workpiece 290 is rotated about an axis 250 in the center of the workpiece 290 parallel to the z-axis, and then passed under the extraction aperture 35 again. In one embodiment, the workpiece 290 is rotated 22.5° and passed under the extraction aperture 35 again. This may be repeated until the workpiece 290 has been rotated 360°, at which point the process is complete. Of course, the regions illustrated in FIG. 4 may be different for each pass of the workpiece 290. The results of this processing can be seen in FIG. 3B, where the surface non-uniformity of the post-processed workpiece 291 has been reduced to about 20 angstroms. This is achieved by etching some material from all portions of the workpiece 290, but more material is etched from the thicker portions.

Since the ribbon ion beam 60 is wider than the workpiece 290, it may not be possible to create the desired pattern using only one pass. Thus, multiple passes wherein the workpiece 290 is rotated after each pass allow for more complex and asymmetrical processing patterns.

While FIG. 3A-3B and FIG. 4 are described in the context of a dry etch process, the disclosure in not limited to this embodiment. In another embodiment, the plasma chamber 30 of FIG. 1 is used to implant impurities into the surface of the workpiece 290 which alter the surface's resistance to an acid bath. As described above, the amount of impurities implanted may be regulated by modulating the extraction voltage duty cycle and rotating the workpiece a plurality of times, as described above. Thus, the system and method described herein can be used to condition the surface of a workpiece prior to a wet etch process.

Returning to FIGS. 2A-2C, the surface of these workpieces 190 may comprise two different materials; a first material used for the fill material 191 and a second material used for the posts 192. In one embodiment, the posts 192 may be silicon nitride (SiN) while the fill material 191 is silicon dioxide (SiO₂). The etching process used to remove the surface non-uniformity may be an etch process which is selective to materials. Chemistries that may be used to selectively etch one material over the second material are well known in the art. For example, C₄F₆ and C₄F₈ may be used to preferentially remove the fill material 191. Alternatively, CH₃F may be used to preferentially remove the posts 192.

Thus, the amount of processing performed on portions or regions of the workpiece 290 may be determined based on the duty cycle of the extraction voltage. Additionally, the use of particular chemistries may determine which materials are processed. The use of particular chemistries to preferentially etch one material may be referred to as a material selective etch process. Material selectivity refers to the etching of a first material substantially faster than a second material.

In summary, the etch process may be incorporate aerial selectivity, material selectivity, or a combination of the two. An aerial-only selective process may process the work piece with noble gasses, such as Ne, Ar, Kr, and Xe, to ‘sputter etch’ or may process the workpiece with Reactive Ion Etch (RIE) using different chemistries well known in the art, but with different amounts across the wafer. For example, a blanket film of one type of material may be processed in this manner. A material selective process may utilize either type of etch (i.e. sputter etch or RIE) to change the material or angle selectivity across a workpiece whose surface is composed of at least two types of materials. Angle selectivity refers to the etching of one type of surface (i.e. horizontal or vertical) substantially faster than a second type of surface. For example, the etch process may remove more SiN than SiO₂ on the edge of the wafer than it does at the center. An aerially and materially selective process may be used to achieve any desired pattern.

Additionally, implantation, amorphization and deposition processes can also be performed using the workpiece processing system 10 and the methods described herein.

In other words, the variation in the duty cycle of the extraction voltage may also be used to create desired processing patterns for deposition, implantation and amorphization as well.

While the above description discloses the use of variable extraction voltage duty cycle to create the desired processing patterns, other parameters can also be varied.

For example, in one embodiment, the workpiece scan velocity, which is the speed at which the workpiece 90 moves relative to the extraction aperture 35, may be varied. For example, to etch, deposit, or implant more material in a particular region, the workpiece 90 may be slowed when this region is exposed to the ribbon ion beam 60. Conversely, when less material is to be deposited, etched or implanted in a particular region, the workpiece 90 may be moved at a higher velocity when this region is exposed to the ribbon ion beam 60. Similarly, more amorphization of the workpiece 90 may be achieved through the use of lower workpiece scan velocities. Therefore, like the previous embodiment, a workpiece 90 may pass through the ribbon ion beam 60 a plurality of times, where the workpiece 90 is rotated after each pass. The workpiece 90 is then translated so that all, or at least some portions, of the workpiece 90 are exposed to the ribbon ion beam 60. The workpiece scan velocity may be variable depending on the region of the workpiece 90 that is currently being exposed to the ribbon ion beam 60.

In another embodiment, the angle of the ribbon ion beam 60 may be varied to achieve the desired pattern. In some embodiments, the etch rate of the material used for the workpiece may be sensitive to the angle of incidence of the ion beam. For example, in one test, it was found that etch rate increases with angle of incidence to a maximum rate, and then decreases as the angle of incident goes beyond the maximum rate. While not wanting to be bound to a particular theory, the increase in etch rate may be due to the increased probability of collisions near the surface of the workpiece. However, past a certain angle of incidence, surface scattering dominates and the etch rate decreases. Thus, the angle of incidence of the ribbon ion beam 60 may be varied as the workpiece 90 is translated relative to the extraction aperture. This may be another parameter than may be varied during processing to achieve a non-uniform processing pattern.

Other parameters can also be modulated to achieve non-uniform processing. For example, parameters such as feedgas flow rate, the amplitude of the extraction voltage, the power applied to the antenna 20, and others, may be varied to achieve these results.

The above embodiments may assume that the ion density of the ribbon ion beam 60 may be relatively uniform or at least non-changing. In other words, in calculating the pattern to be applied during each pass of the workpiece 90, the ion density across the ribbon ion beam 60 may be assumed to be non-changing for each pass. However, in other embodiments, the shape or ion density of the ribbon ion beam 60 may be modified as well.

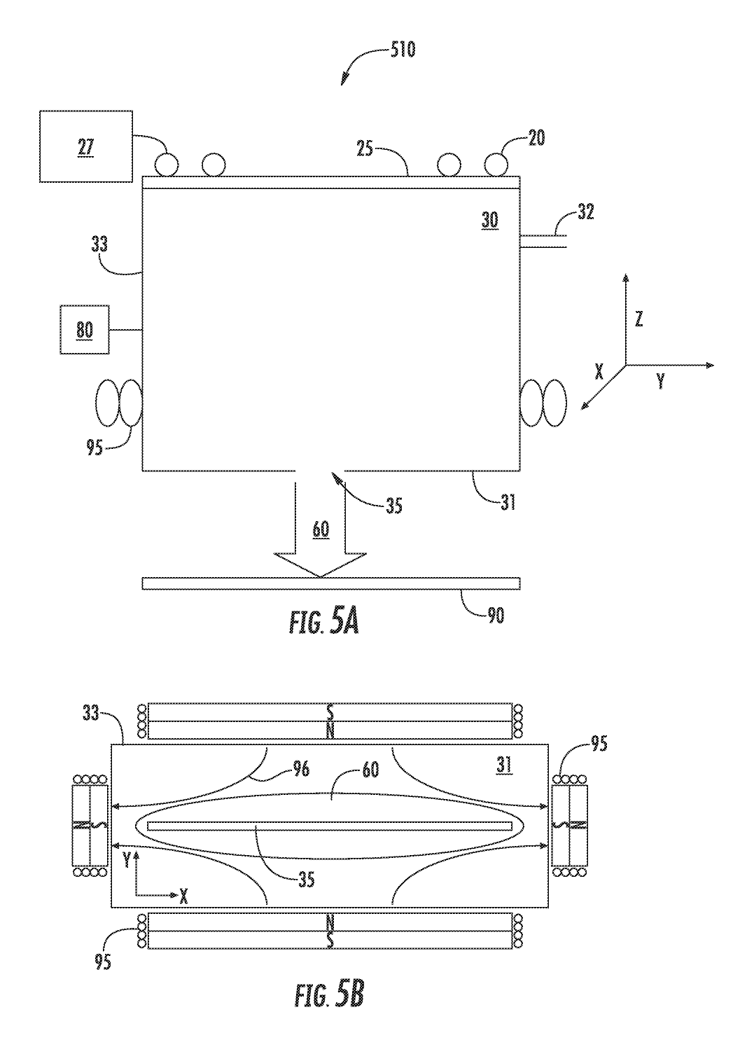

In some embodiments, the ribbon ion beam 60 may be dynamically shaped or altered. FIG. 5A shows a system 510 including a plasma chamber 30, similar to the one illustrated in FIG. 1. All corresponding elements have been given identical reference designators and will not be described again. In this embodiment, electromagnets 95 may be disposed on one or more of the chamber sidewalls 33. The current applied to each of the electromagnets 95 may be independently controllable. FIG. 5B shows a bottom view of the plasma chamber 30 of FIG. 5A. In this view, electromagnets 95 are shown disposed on four chamber sidewalls 33. The interaction between these electromagnets 95 creates magnetic field 96, which serves to confine or deflect the ribbon ion beam 60. By modifying the current passing through each electromagnet 95, the magnetic field 96 can be controlled, allowing more control over the overall shape and ion density of the ribbon ion beam 60.

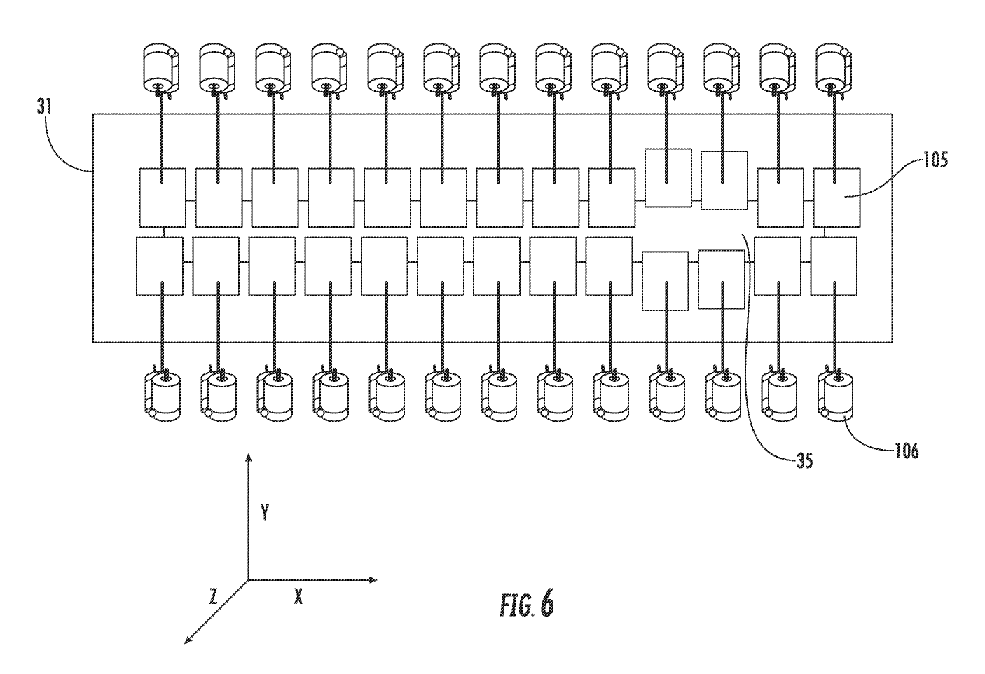

FIG. 6 shows a second embodiment of a plasma chamber 30 to dynamically control the shape and/or ion density of the ribbon ion beam 60. FIG. 6 shows a bottom view of a plasma chamber 30, wherein a plurality of blockers 105 is disposed along the length of the extraction aperture 35 proximate the chamber wall 31. The blockers 105 and the actuators 106 may be external to the plasma chamber 30. In some embodiments, each of the blockers 105 is in communication with a respective actuator 106. In other embodiments, more than one blocker 105 may be in communication with a single actuator 106. Each actuator 106 is capable of translating its respective blocker 105 in the y-direction. FIG. 6 shows blockers 105 disposed on both sides of the extraction aperture 35; however, in other embodiments, blockers 105 may be disposed only on one side of the extraction aperture 35. By translating the blockers 105 in the y-direction, the effective width of the extraction aperture 35 can be manipulated. Furthermore, because, in some embodiments, the blockers 105 are independently controlled, the shape and ion density of the ribbon ion beam 60 can be manipulated. For example, the blockers 105 toward the center of the extraction aperture 35 may be actuated so as to block a greater percentage of the extraction aperture 35 than the blockers 105 disposed near the ends of the extraction aperture 35. This may effectively increase the ion density near the ends of the extraction aperture 35 while reducing the ion density close to the center of the extraction aperture 35. Of course, other configurations of the blockers 105 are also possible.

While FIG. 5A-5B and FIG. 6 illustrate two embodiments where the shape of the ribbon ion beam 60 can be manipulated, other mechanisms are also possible. This manipulation may be electromagnetic or electrical in nature, such as through the use of electrodes or electromagnets 95. Alternatively, this manipulation may be mechanical, such as through the use of blockers 105. Of course, other methods of manipulating the ribbon ion beam 60 may also be used and the disclosure is not limited to any particular embodiment.

In some embodiments, the manipulation of the ribbon ion beam 60 is used in conjunction with other techniques, such as the variation of the extraction voltage duty cycle. For example, the workpiece 90 may be passed through the ribbon ion beam 60 a plurality of times, where the extraction voltage duty cycle is varied during each pass. After each pass, the workpiece 90 may be rotated and subjected to another pass. Additionally, the ribbon ion beam 60 may be manipulated during each pass. In other embodiments, the ribbon ion beam 60 may be manipulated once before the plasma processing begins, and may not be manipulated again.

In other embodiments, the manipulation of the ribbon ion beam 60 may be used without the use of any other techniques, such as variation of the extraction voltage duty cycle. For example, the ribbon ion beam 60 may be manipulated as the workpiece 90 passes through the ribbon ion beam 60. For example, in this way, the ribbon ion beam 60 may be manipulated to create any desired pattern in the workpiece 90 in one pass. In some embodiments, additional passes are also performed to improve the quality of the processing operation.

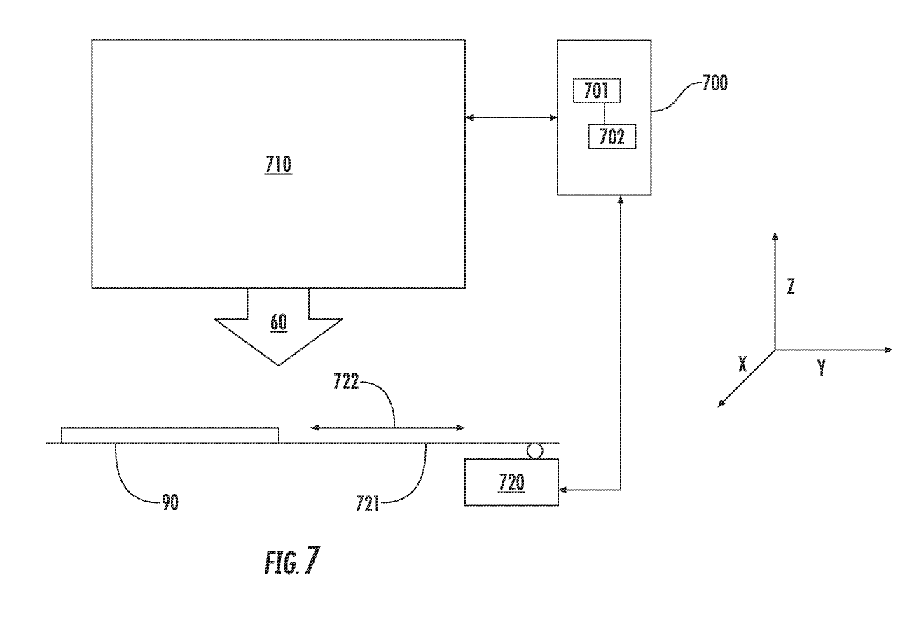

To perform the plasma processing described herein, the system 710 may be in communication with a controller 700, as shown in FIG. 7. The system 710 may be any of the embodiments shown in FIGS. 1, 5A-5B, or 6. The controller 700 may comprise a processing unit 701 in communication with a non-transitory storage element 702, such as a memory device. The non-transitory storage element 702 may comprise instructions, which when executed by the processing unit 701, allow the system 710 to perform the desired plasma processing.

The controller 700 is in communication with the system 710, and as such, may be able to control a plurality of parameters, such as, but not limited to extraction voltage duty cycle, extraction voltage amplitude, RF power, feedgas flow rate, the angle of incidence of the ribbon ion beam 60, and devices used for the manipulation of the ribbon ion beam 60, such as electromagnets 95 or blockers 105 (see FIGS. 5A-5B and FIG. 6).

The workpiece 90 may be disposed on a movable surface 721, such as a conveyer belt, which translates the workpiece 90 in the y-direction 722 relative to the extraction aperture 35 and the ribbon ion beam 60. The movable surface 721 may be moved using an actuator 720. In some embodiments, the controller 700 is in communication with the actuator 720, so that the controller 700 can modify the workpiece scan velocity and/or direction. In some embodiments, the actuator 720 may be able to rotate the workpiece 90 about an axis parallel to the z-direction, as described above.

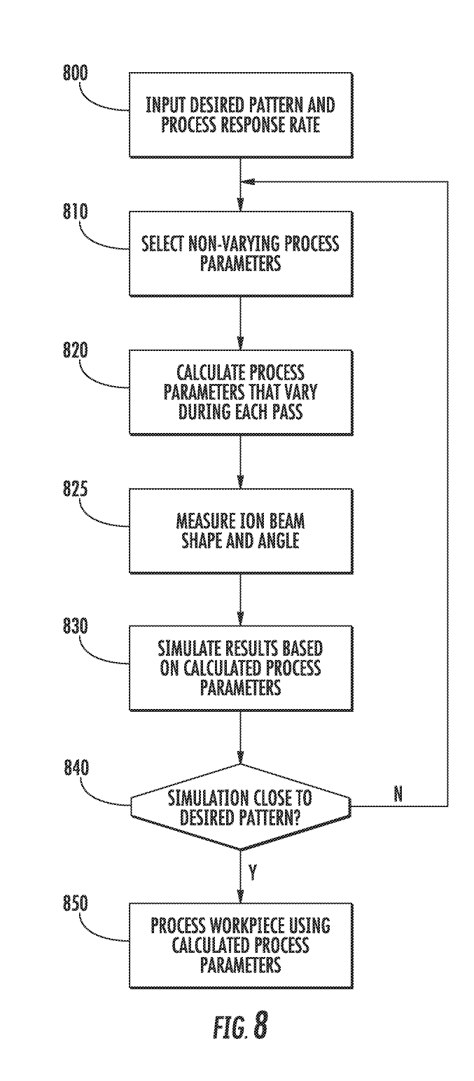

FIG. 8 shows a flowchart illustrating a representative sequence executed by the controller 700. First, the desired pattern is input to the controller 700, as shown in process 800. The controller 700 may receive this input in a variety of ways. For example, in some embodiments, the system 710 may be used to etch or deposit material on a workpiece 90. In these embodiments, the workpiece 90 prior to being processed by system 710 may not be of uniform thickness. Thus, the system 710 may etch or deposit material in a non-uniform manner so that the resulting workpiece is planar (i.e. has uniform thickness). In other embodiments, the system 710 may process the workpiece 90 so as to create a non-uniformity. In yet another embodiment, the workpiece 90 prior to being processed by system 710 may not be of uniform thickness, and the system 710 may process the workpiece 90 so as to create a different pattern of non-uniform thickness, in anticipation of processing by a subsequent process. In these embodiments, the input to the controller 700 may be a topology map of the workpiece 90, similar to that shown in FIG. 3A. This topology map may be generated using a vision system or by some other means. In other embodiments, this topology map may be pre-defined based on theoretical or empirical measurements taken on a previously processed workpiece 90. In the case of an implant or amorphization process, the desired pattern may be entered into the controller 700 in a different way. Additionally, other parameters, such as but not limited to process type (etch, deposition, implant, amorphization), dose, number of passes of the workpiece, and number of rotations, may also be input into the controller 700.

Additionally, process response rates may be entered into the controller 700. Each material has a known response rate, which depends on duty cycle of the extraction voltage, the amplitude of the extraction voltage, the angle of incidence and ion density of the ribbon ion beam 60, and other parameters. The response rate may be the rate at which material is etched from a workpiece, of the rate at which material is deposited on a workpiece. These response rates may be calculated theoretically or empirically and entered into the controller 700.

Based on this information, the controller 700 may select certain parameters that do not vary while the workpiece 90 is being processed, as shown in process 810. For example, one or more parameters may remain constant when the workpiece is being processed. For example, in one embodiment, the ribbon ion beam may be manipulated to achieve a desired result. In other embodiments, other parameters, such as RF power, dose, the angle of incidence of the ribbon ion beam 60, the feed gas flow rate or amplitude of extraction voltage may remain constant during workpiece processing. All of these non-varying process parameters are selected by the controller 700 in process 810.

Further, based on the input information, the controller 700 may calculate a set of variable process parameters to be used for each pass of the workpiece 90, as shown in process 820. As described above, in some embodiments, some parameters are maintained at constant values, while one or more parameters is varied during the processing of the workpiece. For example, certain parameters such as RF power, dose, feedgas flow rate and amplitude of extraction voltage may be maintained at a constant value, while parameters, such as the extraction voltage duty cycle, the shape and angle of incidence of the ribbon ion beam and the workpiece scan velocity may be varied during the processing of the workpiece 90. If more than one pass of the workpiece is desired, the controller 700 may generate the appropriate set of parameters for each pass, where the parameters used for one pass may not be the same as those used during a subsequent pass.

In some embodiments, the shape and angle of the ribbon ion beam 60 may be measured to insure that the ion beam is properly calibrated, prior to processing the workpiece 90, as shown in process 825.

Next, the controller 700 simulates the result, assuming that the calculated set of process parameters is applied to a workpiece, as shown in process 830.

The controller 700, in process 840, then compares the desired pattern to the simulated result created in process 830. If the comparison is sufficiently close, the controller 700 then applies these calculated process parameters to the system 710, which then processes the workpiece 90, as shown in process 850. If, however, the simulated result is not sufficiently close, the controller 700 may return to process 810, where the controller 700 varies one or more of the non-varying parameters. For example, in one embodiment, the shape of the ribbon ion beam 60 may be a non-varying process parameter. If the simulated result is not sufficiently close, the shape of the ribbon ion beam 60 may be manipulated differently in process 810. The controller 700 then repeats processes 810-840 until the difference between the simulated result and the desired pattern is sufficiently small.

While FIG. 8 discloses a sequence to remove a non-uniformity, such as workpiece thickness non-uniformity, from an incoming workpiece, other embodiments are also possible. For example, it may be known that a subsequent process, such as anneal, chemical-mechanical planarization (CMP), or the like, may have inherent non-uniformities. For example, it may be known that a CMP station removes more material from the center of a workpiece than from the edges. In this embodiment, the sequence of FIG. 8 may be used to process the workpiece 90 so that the sequence anticipates and compensates for the future non-uniformity. In other words, in this example, the sequence of FIG. 8 may be used to create a workpiece that is thicker in the center than at the edges, knowing that the inherent non-uniformity of the CMP station will result in a uniformly thick workpiece.

The described system and method have many advantages. The system and method allow the creation of any desired processing pattern using a plasma chamber. By manipulating at least one parameter of the plasma chamber while the workpiece is being translated relative to the ribbon ion beam, it may be possible to non-uniformly process the workpiece. For example, as shown in FIGS. 3A-3B, a workpiece having a non-uniform thickness may be processed in accordance with these embodiments to create a workpiece with improved uniformity in terms of thickness. Additionally, the present system and method may be used for a variety of processes, such as etching, implanting, deposition and amorphization. Furthermore, this system and method can be used to compensate for expected non-uniform processing in a subsequent process.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of processing a workpiece using a plasma chamber, comprising:
extracting a ribbon ion beam through an extraction aperture of the plasma chamber;
translating the workpiece relative to the plasma chamber so that different portions of the workpiece are exposed to the ribbon ion beam; and
varying at least one parameter of the plasma chamber while the workpiece is being translated.

2. The method of claim 1, further comprising:
rotating the workpiece after at least some portions of the workpiece have been exposed to the ribbon ion beam; and
repeating the translating, varying and rotating a plurality of times to achieve a desired pattern.

3. The method of claim 1, wherein an extraction voltage is applied to walls of the plasma chamber; and the at least one parameter comprises a duty cycle of the extraction voltage.

4. The method of claim 1, wherein the at least one parameter comprises a shape of the ribbon ion beam, and wherein the shape of the ribbon ion beam is varied by mechanical blockers, electromagnets or electrodes.

5. The method of claim 1, wherein the at least one parameter comprises an angle of incidence of the ribbon ion beam.

6. The method of claim 1, wherein the at least one parameter comprises a velocity at which the workpiece is translated relative to the plasma chamber.

7. The method of claim 1, wherein the processing comprises etching, deposition, implantation or amorphization.

8. The method of claim 1, wherein the processing is performed non-uniformly such that a first region of the workpiece is processed more than a second region.

9. The method of claim 8, wherein the workpiece has non-uniform thickness prior to the processing.

10. The method of claim 8, wherein the workpiece has non-uniform thickness after the processing.

11. The method of claim 1, wherein the workpiece comprises a first material and a second material and the processing processes the first material more than the second material.

12. A method of etching a workpiece having non-uniform thickness, comprising:
determining an etch pattern that removes the non-uniform thickness; and
applying the etch pattern to the workpiece using a ribbon ion beam extracted from a plasma chamber.

13. The method of claim 12, wherein the workpiece is translated relative to the ribbon ion beam so as to expose different portions of the workpiece and a parameter associated with the plasma chamber is varied as the workpiece is translated.

14. The method of claim 13, wherein the workpiece is exposed to the ribbon ion beam a plurality of times and is rotated after each exposure.

15. A system for processing a workpiece comprising:
a plasma chamber having an extraction aperture from which a ribbon ion beam is extracted;
a movable surface on which the workpiece is disposed so as to pass proximate the extraction aperture; and
a controller;
wherein the controller is configured to vary one or more parameters of the plasma chamber while the workpiece is passing the extraction aperture.

16. The system of claim 15, further comprising an extraction voltage power supply in communication with walls of the plasma chamber to supply an extraction voltage, wherein the controller varies a duty cycle of the extraction voltage.

17. The system of claim 15, wherein the controller varies a shape or an angle of incidence of the ribbon ion beam.

18. The system of claim 17, further comprising blockers disposed proximate the extraction aperture and actuators in communication with the blockers so as to move the blockers, wherein the controller is in communication with the actuators.

19. The system of claim 17, further comprising electromagnets disposed proximate walls of the plasma chamber, wherein the controller is in communication with the electromagnets.

20. The system of claim 15, further comprising an actuator to adjust a speed of the movable surface, wherein the controller is in communication with the actuator so as to vary the speed of the movable surface.
